(19) United States
(12) Patent Application Publication
(10) Pub. No.: US 2025/0293210 A1
(43) Pub. Date: Sep. 18, 2025

(54) SYSTEMS AND METHODS FOR PACKAGING A SEMICONDUCTOR DEVICE

(71) Applicant: Advanced Micro Devices, Inc., Santa Clara, CA (US)

(72) Inventors: Arsalan Alam, Austin, TX (US); Anadi Srivastava, Austin, TX (US); Chandra Sekhar Mandalapu, Fort Collins, CO (US); Chia-Hao Cheng, Taipei (TW); Liwei Wang, Austin, TX (US); Raja Swaminathan, Austin, TX (US)

(73) Assignee: Advanced Micro Devices, Inc., Santa Clara, CA (US)

(21) Appl. No.: 18/176,393

(22) Filed: Feb. 28, 2023

(51) Int. Cl. H01L 25/065; H01L 21/56; H01L 23/31; H01L 23/36; H01L 25/00

(52) U.S. Cl. CPC H01L 25/0657; H01L 21/56; H01L 23/3107; H01L 23/36; H01L 25/50

(57) ABSTRACT

The disclosed semiconductor device can include a plurality of stacked circuit dies and a mold compound introduced into a top tier of the plurality of stacked circuit dies. The disclosed semiconductor device also includes a carrier-less enclosure attached to the top tier of the plurality of stacked circuit dies. Various other methods, systems, and computer-readable media are also disclosed.

### BACKGROUND

3D stacked technology provides the advantages of enabling heterogeneous integration of chiplets with fine vertical stacking pitches and increased performance compared to other technologies that enable heterogenous integration. Related packaging methodologies can include multiple dies inside a same package. For example, multiple chips can be arranged in a planar or stacked configuration for multiple tiers of stacked circuit dies. A resulting semiconductor device can be enclosed by introducing electrolytic gap filler by chemical vapor deposition (CVD) in a clean environment, thinning a top tier of the stacked circuit dies, and hybrid bonding a silicon carrier to the top tier of stacked circuit dies.

### BRIEF DESCRIPTION OF THE DRAWINGS

The accompanying drawings illustrate a number of example embodiments and are a part of the specification. Together with the following description, these drawings demonstrate and explain various principles of the present disclosure.

FIG. 1 is a flow diagram of an example method for packaging a semiconductor device.

FIG. 2 is a block diagram illustrating an example semiconductor device that includes a silicon carrier.

FIG. 3 is a block diagram illustrating example semiconductor devices that include a mold compound and/or a heat spreader instead of a silicon carrier.

FIG. 4 is a block diagram illustrating an example semiconductor device having a mold compound and a discontinuous heat spreader instead of a silicon carrier.

FIG. 5 is a block diagram illustrating an example semiconductor device that includes N-tier stacked circuit dies with a top tier being enclosed by a mold compound and/or a heat spreader instead of a silicon carrier.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to systems and methods for packaging a semiconductor device. The existing process of thinning of the top tier of stacked circuit dies and hybrid bonding a silicon carrier atop the circuit dies adds cost to the packaging process and thermally insulates the top tier in a manner that is detrimental to heat dissipation. Instead of using a silicon carrier to enclose the top tier of the semiconductor device, the disclosed systems and methods use a thermally conductive mold compound and/or heat spreader to enclose the top tier circuit dies, and the top tier circuit dies can be thicker to simplify process flow and aid in heat dissipation.

In one example, a semiconductor device includes a plurality of stacked circuit dies, a mold compound introduced into a top tier of the plurality of stacked circuit dies, and a carrier-less enclosure attached to the top tier of the plurality of stacked circuit dies.

Another example can be the previously described example semiconductor device, wherein the plurality of stacked circuit dies includes at least one lower tier of one or more additional circuit dies.

Another example can be any of the previously described example semiconductor devices, further comprising an additional mold compound introduced into the at least one lower tier of the plurality of stacked circuit dies, wherein the additional mold compound is different from the mold compound introduced into the top tier of the plurality of stacked circuit dies.

Another example can be any of the previously described example semiconductor devices, wherein the carrier-less enclosure includes a heat spreader attached to one or more circuit dies included in the top tier of the plurality of stacked circuit dies.

Another example can be any of the previously described example semiconductor devices, wherein the heat spreader is discontinuous.

Another example can be any of the previously described example semiconductor devices, wherein the heat spreader is patterned to provide die-to-die isolation of the one or more circuit dies included in the top tier of the plurality of stacked circuit dies.

Another example can be any of the previously described example semiconductor devices, wherein the heat spreader is continuous.

Another example can be any of the previously described example semiconductor devices, wherein the carrier-less enclosure includes an extension of the mold compound above one or more circuit dies included in the top tier of the plurality of stacked circuit dies.

Another example can be any of the previously described example semiconductor devices, wherein one or more circuit dies included in the top tier of the plurality of stacked circuit dies has a thickness greater than another thickness of one or more additional circuit dies included in at least one lower tier of the plurality of stacked circuit dies.

Another example can be any of the previously described example semiconductor devices, wherein the mold compound comprises a non-dielectric insulator introduced between one or more circuit dies included in the top tier of the plurality of stacked circuit dies.

Another example can be any of the previously described example semiconductor devices, wherein the semiconductor device does not include any dielectric gap filler introduced between one or more circuit dies included in the top tier of the plurality of stacked circuit dies.

In one example, a semiconductor device enclosure includes a mold compound introduced into a top tier of a plurality of stacked circuit dies, and a heat spreader attached to one or more circuit dies included in the top tier of the plurality of stacked circuit dies, wherein the mold compound and the heat spreader form a carrier-less enclosure of the top tier of the plurality of stacked circuit dies.

Another example can be the previously described example semiconductor device enclosure, wherein the heat spreader is discontinuous and patterned to provide isolation of the one or more circuit dies included in the top tier of the plurality of stacked circuit dies.

Another example can be any of the previously described example semiconductor device enclosures, wherein the mold compound comprises a non-dielectric insulator introduced between the one or more circuit dies included in the top tier of the plurality of stacked circuit dies.

In one example, a method can include preparing a plurality of stacked circuit dies to receive a mold compound into a top tier of the plurality of stacked circuit dies, introducing the mold compound into the top tier of the plurality of stacked circuit dies, and forming a carrier-less enclosure of the top tier of the plurality of stacked circuit dies.

Another example can be the previously described method, wherein forming the carrier-less enclosure includes attaching a heat spreader to one or more circuit dies included in the top tier of the plurality of stacked circuit dies.

Another example can be any of the previously described methods, wherein the heat spreader is discontinuous and patterned to provide die-to-die isolation of the one or more circuit dies included in the top tier of the plurality of stacked circuit dies.

Another example can be any of the previously described methods, wherein forming the carrier-less enclosure includes extending the mold compound above one or more circuit dies included in the top tier of the plurality of stacked circuit dies.

Another example can be any of the previously described methods, wherein one or more circuit dies included in the top tier of the plurality of stacked circuit dies has a thickness greater than another thickness of one or more additional circuit dies included in at least one lower tier of the plurality of stacked circuit dies.

Another example can be any of the previously described methods, wherein the mold compound comprises a non-dielectric insulator introduced between one or more circuit dies included in the top tier of the plurality of stacked circuit dies.

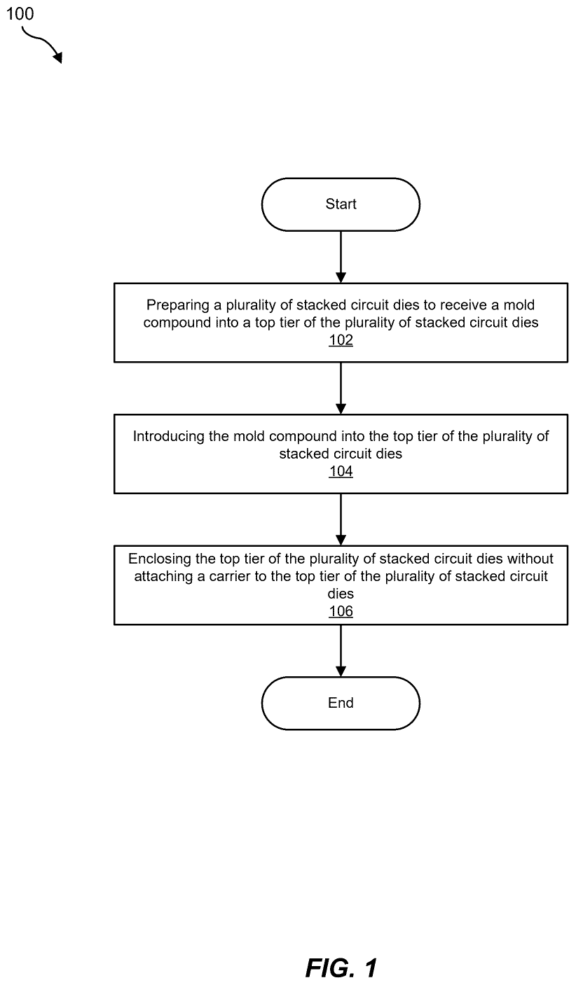

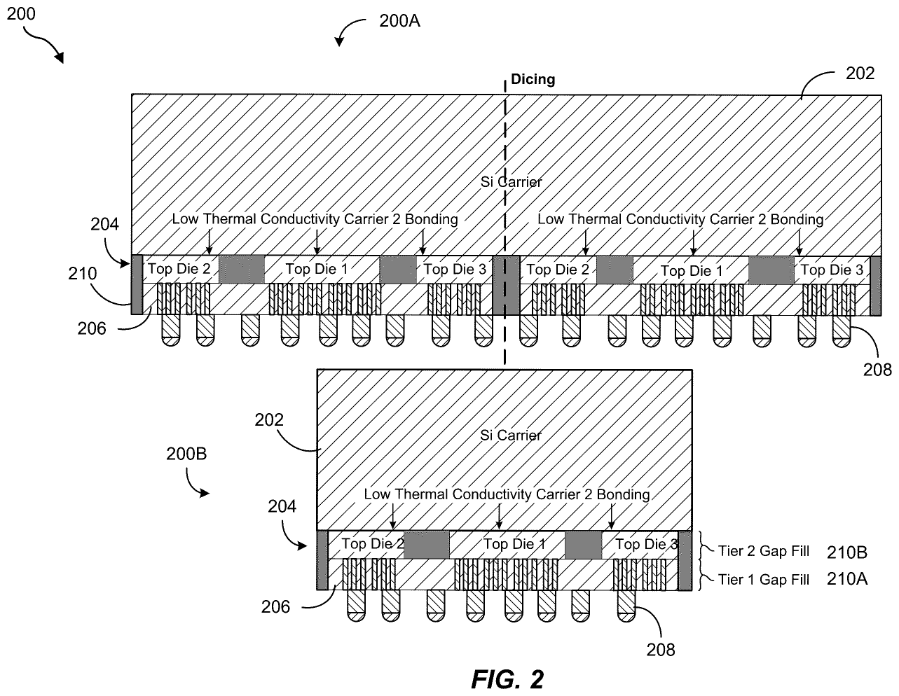

The following will provide, with reference to FIG. 1, detailed descriptions of example methods for packaging a semiconductor device. Detailed descriptions of example semiconductor devices will also be provided in connection with FIGS. 2-5.

FIG. 1 is a flow diagram of an example computer-implemented method 100 for packaging a semiconductor device. The steps shown in FIG. 1 can be performed by any suitable manufacturing process, computer-executable code, and/or computing system. In one example, each of the steps shown in FIG. 1 can represent an algorithm whose structure includes and/or is represented by multiple sub-steps, examples of which will be provided in greater detail below.

As illustrated in FIG. 1, at step 102 packaging a semiconductor device can include preparing stacked circuit dies. For example, packaging a semiconductor device can include preparing a plurality of stacked circuit dies to receive a mold compound into a top tier of the plurality of stacked circuit dies.

The term “semiconductor device,” as used herein, can generally refer to an electronic component that relies on the electronic properties of a semiconductor material for its function. For example, and without limitations, a semiconductor device can rely on one or more semiconductor materials, such as silicon, germanium, gallium arsenide, organic semiconductors, etc. A semiconductor device's conductivity can lie between conductors and insulators. Semiconductor devices can be manufactured as single discrete devices and/or as integrated circuit (IC) chips that include multiple devices manufactured and interconnected on a single semiconductor wafer (e.g., a substrate). In this context, “stacked circuit dies” can refer to multiple wafers stacked one atop another.

The term “circuit die,” as used herein, can generally refer to a small block of semiconducting material on which a given functional circuit is fabricated. For example, and without limitation, integrated circuits can be produced in large batches on a single wafer of electronic-grade silicon (EGS) or other semiconductor through processes such as photolithography.

The term “mold compound,” as used herein, can generally refer to an insulator. Example mold compounds can include, without limitation, epoxy, plastic, rubber, silicone, etc. Mold compounds can be thermal insulators and/or electrical insulators. For example, epoxy can be an excellent electrical insulator while having good thermal conductivity that permits a beneficial amount of heat dissipation. Mold compounds can frequently be characterized as plastics used to encapsulate many types of electronic packages. Mold compounds can be dielectric or non-dielectric, with non-dielectric mold compounds being significantly less expensive than dielectric mold compounds. While some non-dielectric mold compounds can become dielectric under certain conditions, a non-dielectric mold compound does not become dielectric under normal operating conditions for a semiconductor device in which it is used. Epoxy can be an inexpensive, non-dielectric mold compound that provides excellent electrical insulation and good thermal conductivity without requiring costly and complicated process flow. In contrast, gap filler can be a relatively expensive type of dielectric epoxy requiring chemical vapor deposition in an ultra-clean fabrication environment.

The term “top tier,” as used herein, can generally refer to a wafer layer on a side opposite a wafer layer to which bumps are provided. For example, and without limitation, a top tier can refer to a wafer layer that is fabricated last in 3D process flow in which stacked wafers are sequentially fabricated one atop another and bumps are provided to a lowest tier. In this context, one or more lower tiers of additional circuit dies can be arranged beneath the top tier in a 3D stack of wafers. The resulting semiconductor device may be flipped for installation, in which case the top tier may become positioned beneath the lower tier or tiers.

The systems described herein can perform step 102 in a variety of ways. In one example, preparing the stacked circuit dies can include positioning the stacked circuit dies (e.g., on a workstation) in a manner that facilitates introduction of the mold compound into the top tier. In some of these examples, the stacked circuit dies can be positioned to facilitate the introduction of the mold compound at an outsourced semiconductor assembly and test (OSAT) facility. In some examples, preparing the stacked circuit dies can include providing the plurality of stacked circuit dies. In other examples, preparing the stacked circuit dies can include fabricating the plurality of stacked circuit dies. In some of these examples, fabricating the plurality of stacked circuit dies can be performed at an ultra-clean fabrication facility at which the stacked circuit dies can be fabricated by thinning and stacking the dies with bonding techniques, and filling gaps between and/or around the circuit dies using a chemical vapor deposition (CVD) process. In some examples, circuit dies of the top tier have not been subjected to thinning during fabrication of the stacked circuit dies. Thus, one or more circuit dies included in a top tier of the plurality of stacked circuit dies can have a thickness greater than another thickness of one or more additional circuit dies included in at least one lower tier of the plurality of stacked circuit dies. In some implementations, one or more circuit dies included in a top tier of the plurality of stacked circuit dies can have a thickness greater than one or more other thicknesses of all additional circuit dies included in all lower tiers of the plurality of stacked circuit dies.

At step 104, packaging a semiconductor device can include introducing a mold compound. For example, packaging a semiconductor device can include introducing a mold compound into the top tier of the plurality of stacked circuit dies.

The systems described herein can perform step 104 in a variety of ways. In one example, the mold compound can include an insulator, such as a non-dielectric insulator, introduced between one or more circuit dies included in the top tier of the plurality of stacked circuit dies. In some of these examples, the non-dielectric insulator can comprise epoxy, such as an inexpensive, non-dielectric epoxy that functions as an electrical insulator but not as a thermal insulator. Additionally or alternatively, the non-dielectric insulator can comprise rubber, plastic, silicone, or any other suitable mold material. In some of these examples, an amount of the non-dielectric insulator introduced into the top tier can exceed an amount (e.g., small, incidental amount) of dielectric gap filler already present in the top tier due to fabrication of the stacked circuit dies at an ultra-clean fabrication facility. According to various examples, the introduction of the mold compound can occur by injecting, pouring, and/or otherwise depositing the mold compound between and/or beside one or more circuit dies of the top tier. One or more of these processes can be performed at an OSAT facility.

At step 106, packaging a semiconductor device can include enclosing the top tier. For example, packaging a semiconductor device can include forming a carrier-less enclosure of the top tier of the plurality of stacked circuit dies.

The term “carrier,” as used herein, can generally refer to a layer of material that ensures integrity and cleanliness of a wafer in a semiconductor device. For example, and without limitation, carriers used in wafer stacks can be made of silicon or any other material, such as glass. A carrier substrate can be used at a bottom of the stack for depositing stacked wafers, a top carrier can be bonded to the top tier circuit dies, and the carrier substrate can be removed. Thus, one or more carriers can be temporarily and/or permanently attached to one or more wafers during manufacture of a semiconductor device. Top carriers can provide protection to semiconductor wafers in front-end and back-end fabrication. In this context, the carrier-less enclosure does not include a top carrier (e.g., silicon or glass) thermally bonded to the top tier of stacked circuit dies, thus avoiding low thermal conductivity bonding of the top carrier that adversely impacts heat dissipation for the top tier circuit dies.

The systems described herein can perform step 106 in a variety of ways. In one example, forming the carrier-less enclosure can include attaching a heat spreader to (e.g., on top of) one or more circuit dies included in the top tier of the plurality of stacked circuit dies. The heat spreader can be attached to the one or more circuit dies without low thermal conductivity bonding. For example, the mold compound can hold the heat spreader in place atop the circuit dies of the top tier. In some of these examples, the heat spreader can be continuous. In other examples, the heat spreader can be discontinuous. In some examples, the heat spreader can be patterned to provide die-to-die isolation of the one or more circuit dies included in the top tier of the plurality of stacked circuit dies. In other examples, forming the carrier-less enclosure can include extending the mold compound above one or more circuit dies included in the top tier of the plurality of stacked circuit dies. In some of these examples, the mold compound can fully enclose the top tier without attaching a heat spreader. In some examples, forming the carrier-less enclosure can be performed without subjecting one or more circuit dies included in the top tier of the plurality of stacked circuit dies to thinning. In other examples, forming the carrier-less enclosure can be performed by enclosing one or more circuit dies included in the top tier of the plurality of stacked circuit dies that are subjected to a reduced amount of thinning compared to one or more additional dies (e.g., at least one additional die, most additional dies, or all additional dies) included in one or more lower tiers (e.g., at least one lower tier, most lower tiers, or all lower tiers) of the plurality of stacked circuit dies. As a result, one or more circuit dies included in a top tier of the plurality of stacked circuit dies can have a thickness greater than another thickness of one or more additional circuit dies included in at least one lower tier of the plurality of stacked circuit dies. In some implementations, one or more circuit dies included in a top tier of the plurality of stacked circuit dies can have a thickness greater than one or more other thicknesses of all additional circuit dies included in all lower tiers of the plurality of stacked circuit dies. In some of these examples, the one or more circuit dies included in the top tier of the plurality of stacked circuit dies can be significantly thicker than the one or more additional dies. In some of these examples, the one or more circuit dies included in the top tier of the plurality of stacked circuit dies can be at least M times as thick as the one or more additional dies, wherein M is a real number greater than one. In some examples, forming the carrier-less enclosure can be performed without introducing any dielectric gap filler between one or more circuit dies included in the top tier of the plurality of stacked circuit dies. In some of these examples, forming the carrier-less enclosure can be performed without introducing any additional dielectric gap filler between the one or more circuit dies beyond any dielectric gap filler (e.g., an incidental amount) already present in the top tier.

One or more of steps 102-104 can include one or more additional procedures. For example, one or more of steps 102-106 can include removing a carrier substrate attached below the stacked circuit dies. Additionally or alternatively, one or more of steps 102-106 can include attaching bumps to a bottom circuit die of the stacked circuit dies. Additionally or alternatively, one or more of steps 102-106 can include dicing the plurality of stacked circuit dies.

Referring to FIG. 2, example semiconductor devices 200 can be of chip-on-reconstituted-wafer (CoRW) stack construction. For example, semiconductor devices 200 can include a silicon carrier 202 attached to a top layer of circuit dies 204. Additionally, semiconductor devices 200 can include a bottom layer circuit die 206 attached to the top layer of circuit dies 204. Also, semiconductor devices 200 can include a plurality of bumps 208 attached to the bottom layer circuit die 206. Gap fill material 210 can be provided in and/or around the layers of dies, resulting in bottom tier gap fill 210A and top tier gap fill 210B. Dicing of a fabricated semiconductor device 200A can result in semiconductor device 200B as shown.

In order to provide semiconductor devices 200 with silicon carrier 202, top tier circuit dies 204 are thinned and the carrier 202 is attached to enclose the top tier circuit dies 204 by a thermally insulating bonding technique. The thinning of the top tier circuit dies 204 and the bonding of the carrier 202 to tops of the circuit dies 202 has a detrimental impact on heat dissipation from the top tier circuit dies 204.

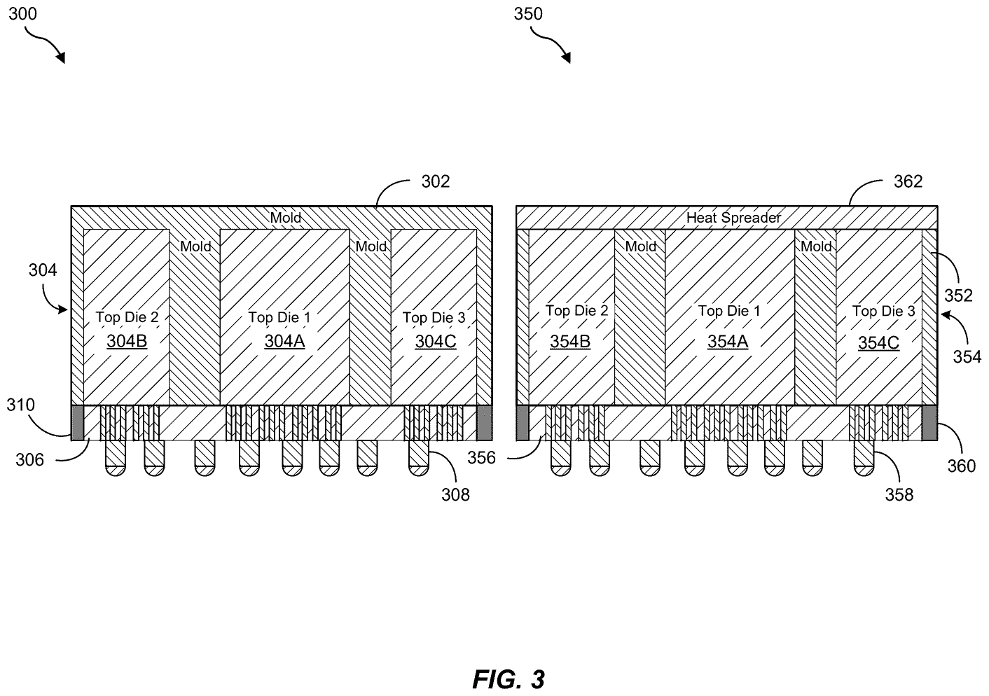

Referring to FIG. 3, semiconductor devices 300 and 350 address the heat dissipation issues for the top tier circuit dies while achieving lower costs for fabrication of the semiconductor device. For example, semiconductor devices 300 and 350 have pluralities of stacked circuit dies with features similar to those described above, including top tier circuit dies 304 and 354, bottom layer circuit dies 306 and 356, bumps 308 and 358, and gap fill material 310 and 360. However, one or more circuit dies 304A-304C and 354A-354C are not thinned or are subjected to a reduced amount of thinning, which aids in heat dissipation. Also, gap fill material 310 and 360 is provided to the bottom layer circuit dies 306 and 356 but not the top tier circuit dies 304 and 354. Nor is a carrier bonded atop the one or more circuit dies 304A-304C and 354A-354C of the top tier. Instead, mold compound 302 and 352 is introduced to the top tier circuit dies 304 and 354. For semiconductor device 300, the mold compound 302 is introduced between and beside the top tier circuit dies 304 and further extended above the top tier circuit dies 304 to enclose the top tier. For semiconductor device 350, the mold compound 352 is introduced between and beside the top tier circuit dies 304 and a heat spreader 362 is attached to the tops of the circuit dies 354A-354C to enclose the top tier. Heat spreader 362 is continuous across the top tier circuit dies 354 and can be attached by mold compound 352 (e.g., epoxy) holding the heat spreader 362 in position atop the one or more circuit dies 354A-354C of the top tier circuit dies 354. This technique for attaching the heat spreader 362 avoids bonding the heat spreader 362 directly to the top tier circuit dies 354A-354C in a manner that can be detrimental to heat dissipation from the top tier circuit dies 354A-354C.

These enclosure techniques further improve heat dissipation for the top tier circuit dies 304 and 354 by allowing use of thicker top tier circuit dies 304 and 354 and avoiding use of a carrier and bonding thereof to the top tier circuit dies 304 and 354. These enclosure techniques also reduce fabrication costs by avoiding use of expensive dielectric gap filler in the top tier, avoiding the need to use an ultra-clean fabrication facility, and avoiding expenses associated with thinning the top tier circuit dies 304 and 354, providing a silicon carrier, and bonding a silicon carrier to the top tier circuit dies 304 and 354.

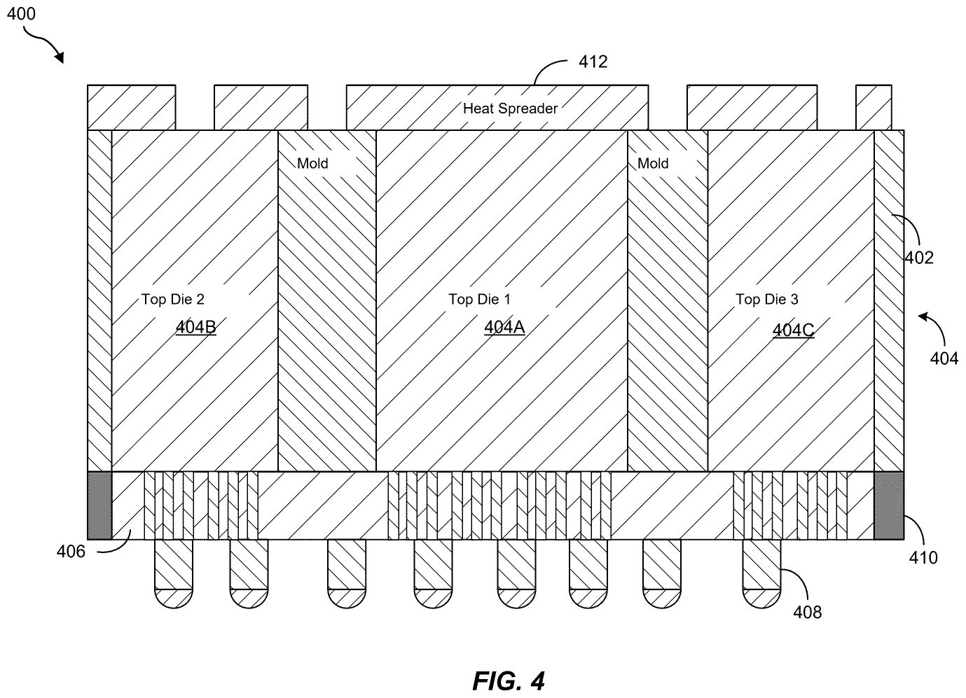

Referring to FIG. 4, another semiconductor device 400 has features similar to the semiconductor device 350 of FIG. 3. For example, semiconductor device 400 has top tier circuit dies 404, bottom layer circuit die 406, bumps 408, and gap fill material 410. Additionally, one or more circuit dies 404A-404C are not thinned or are subjected to a reduced amount of thinning, which aids in heat dissipation. Also, gap fill material 410 is provided to the bottom layer circuit die 406 but not the top tier circuit dies 404. Nor is a carrier bonded atop the one or more circuit dies 404A-404C of the top tier. Instead, mold compound 402 is introduced between and beside the top tier circuit dies 404 and a heat spreader 412 is attached to the tops of the circuit dies 404A-404C to enclose the top tier. However, the heat spreader 412 is discontinuous across the top tier circuit dies 404. The discontinuity of heat spreader 412 can be a result of heat spreader 412 being patterned to provide die-to-die isolation of the one or more circuit dies 404A-404C included in the top tier circuit dies 404. Heat spreader 412 can be attached by mold compound 402 (e.g., epoxy) holding the heat spreader 412 in position atop the one or more circuit dies 404A-404C of the top tier circuit dies 404. This technique for attaching the heat spreader 412 avoids bonding the heat spreader 412 directly to the top tier circuit dies 404 in a manner that can be detrimental to heat dissipation from the top tier circuit dies 404.

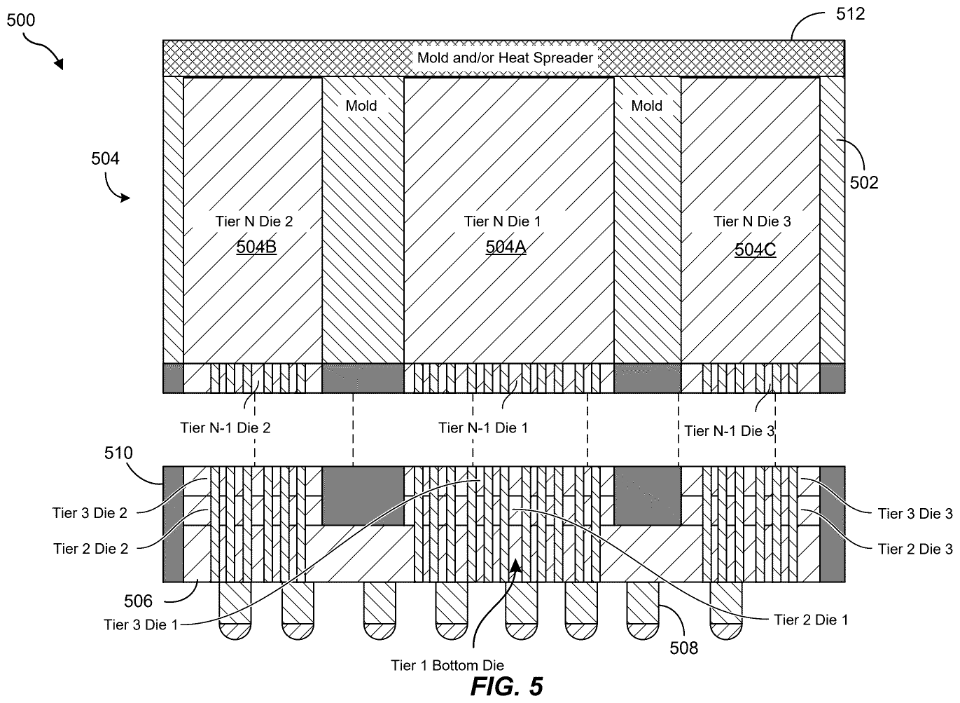

Referring to FIG. 5, example semiconductor device 500 demonstrates that the plurality of stacked circuit dies can include two or more tiers of stacked circuit dies and that a carrier-less enclosure 512 of the semiconductor device 500 can include mold compound 502 and/or a heat spreader. For example, semiconductor device 500 includes N-tier stacked circuit (e.g., N≥2) dies with a top tier 504 of circuit dies 504A-504C being enclosed by a mold compound and/or a heat spreader instead of a silicon carrier. Dielectric gap filler 510 can be provided to lower tier circuit dies, which can include a bottom tier 506 having bumps 508 provided for electrical connection. As a result of subjecting circuit dies 504A-504C included in top tier 504 (e.g., tier N) to no thinning or a reduced amount of thinning compared to dies of one or more lower tiers, circuit dies 504A-504C can be at least M times as thick as the one or more additional dies, wherein M is a real number greater than one. As shown in FIG. 5, circuit dies 504A-504C remain at least five times thicker than a die of the bottom tier 506 (e.g., tier 1 bottom die), and remain more than nine times thicker than dies of other tiers (e.g., tier 2 die 1, tier 2 die 2, tier 2 die 3, tier 3 die 1, tier 3 die 2, tier 3 die 3, tier N−1 die 1, tier N−1 die 2, and tier N−1 die 3). No thinning or reduced thinning of circuit dies 504A-504C reduces fabrication time, reduces costs, and aids in heat dissipation. Although dies of other tiers dies of other tiers (e.g., tier 2 die 1, tier 2 die 2, tier 2 die 3, tier 3 die 1, tier 3 die 2, tier 3 die 3, tier N−1 die 1, tier N−1 die 2, and tier N−1 die 3) are shown in FIG. 5 to be of equal size and thickness, it should be understood that these dies may vary in size and/or thickness.

As set forth above, the disclosed systems and methods introduce mold compound usage to a 3D product process flow, permitting process simplification, cost reduction, and improved thermal response. The disclosed systems and methods also allow top tier stacked dies to be thicker, up to full thickness, further resulting in a simplified process flow and improved thermal response. Finally, the disclosed systems and methods eliminate usage of a top silicon carrier from the stacked product flow, yet further making the overall process flow simpler and less expensive while yielding improved thermal response.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A semiconductor device, comprising:
a plurality of stacked circuit dies;
a mold compound introduced into a top tier of the plurality of stacked circuit dies; and
a carrier-less enclosure attached to the top tier of the plurality of stacked circuit dies.

2. The semiconductor device of claim 1, wherein the plurality of stacked circuit dies includes at least one lower tier of one or more additional circuit dies.

3. The semiconductor device of claim 2, further comprising an additional mold compound introduced into the at least one lower tier of the plurality of stacked circuit dies, wherein the additional mold compound is different from the mold compound introduced into the top tier of the plurality of stacked circuit dies.

4. The semiconductor device of claim 1, wherein the carrier-less enclosure includes a heat spreader attached to one or more circuit dies included in the top tier of the plurality of stacked circuit dies.

5. The semiconductor device of claim 4, wherein the heat spreader is discontinuous.

6. The semiconductor device of claim 5, wherein the heat spreader is patterned to provide die-to-die isolation of the one or more circuit dies included in the top tier of the plurality of stacked circuit dies.

7. The semiconductor device of claim 4, wherein the heat spreader is continuous.

8. The semiconductor device of claim 1, wherein the carrier-less enclosure includes an extension of the mold compound above one or more circuit dies included in the top tier of the plurality of stacked circuit dies.

9. The semiconductor device of claim 1, wherein one or more circuit dies included in the top tier of the plurality of stacked circuit dies has a thickness greater than another thickness of one or more additional circuit dies included in at least one lower tier of the plurality of stacked circuit dies.

10. The semiconductor device of claim 1, wherein the mold compound comprises a non-dielectric insulator introduced between one or more circuit dies included in the top tier of the plurality of stacked circuit dies.

11. The semiconductor device of claim 1, wherein the semiconductor device does not include any dielectric gap filler introduced between one or more circuit dies included in the top tier of the plurality of stacked circuit dies.

12. A semiconductor device enclosure, comprising:
a mold compound introduced into a top tier of a plurality of stacked circuit dies; and
a heat spreader attached to one or more circuit dies included in the top tier of the plurality of stacked circuit dies,
wherein the mold compound and the heat spreader form a carrier-less enclosure of the top tier of the plurality of stacked circuit dies.

13. The semiconductor device enclosure of claim 12, wherein the heat spreader is discontinuous and patterned to provide die-to-die isolation of the one or more circuit dies included in the top tier of the plurality of stacked circuit dies.

14. The semiconductor device enclosure of claim 12, wherein the mold compound comprises a non-dielectric insulator introduced between the one or more circuit dies included in the top tier of the plurality of stacked circuit dies.

15. A method, comprising:
preparing a plurality of stacked circuit dies to receive a mold compound into a top tier of the plurality of stacked circuit dies;
introducing the mold compound into the top tier of the plurality of stacked circuit dies; and
forming a carrier-less enclosure of the top tier of the plurality of stacked circuit dies.

16. The method of claim 15, wherein forming the carrier-less enclosure includes attaching a heat spreader to one or more circuit dies included in the top tier of the plurality of stacked circuit dies.

17. The method of claim 16, wherein the heat spreader is discontinuous and patterned to provide die-to-die isolation of the one or more circuit dies included in the top tier of the plurality of stacked circuit dies.

18. The method of claim 15, wherein forming the carrier-less enclosure includes extending the mold compound above one or more circuit dies included in the top tier of the plurality of stacked circuit dies.

19. The method of claim 15, wherein one or more circuit dies included in the top tier of the plurality of stacked circuit dies has a thickness greater than another thickness of one or more additional circuit dies included in at least one lower tier of the plurality of stacked circuit dies.

20. The method of claim 15, wherein the mold compound comprises a non-dielectric insulator introduced between one or more circuit dies included in the top tier of the plurality of stacked circuit dies.
